(19) United States
(12) Patent Application Publication
(10) Pub. No.: US 2024/0186457 A1
(43) Pub. Date: Jun. 6, 2024

(54) LIGHT EMITTING DIODE STRUCTURE

(71) Applicant: Taiwan-Asia Semiconductor Corporation, Hsinchu City (TW)

(72) Inventor: Kun-Te LIN, Hsinchu City (TW)

(21) Appl. No.: 18/491,926

(22) Filed: Oct. 23, 2023

(30) Foreign Application Priority Data
Dec. 6, 2022 (TW) 111146733

(51) Int. Cl. H01L 33/44; H01L 33/38

(52) U.S. Cl. CPC H01L 33/44; H01L 33/38

(57) ABSTRACT

The present invention provides a light emitting diode structure, including a substrate, a semiconductor light emitting structure, an electrode, and a protection structure. The semiconductor light-emitting structure is located on the substrate, and the semiconductor light-emitting structure includes a top surface. The electrode is located on the top surface, and the electrode includes a pad portion and at least one extension portion. One end of each extension portion is connected to the pad portion, and the pad portion has a first maximum height away from the top surface. The protection structure is located on the top surface and connected to the electrode, and the protection structure has a second maximum height away from the top surface. Wherein the second maximum height is greater than the first maximum height.

### CROSS-REFERENCES TO RELATED APPLICATIONS

This application claims the benefit of priority to Taiwanese Patent Application No. 111146733 filed on Dec. 6, 2022, which is hereby incorporated by reference in its entirety.

### BACKGROUND OF THE INVENTION

### Field of the Invention

The present invention relates to a light emitting diode structure, in particular a light emitting diode structure with an effect of protecting electrodes.

### Descriptions of the Related Art

In recent years, light-emitting diodes have been widely used in lighting, medical and 3C products. Light-emitting diode chips are mainly made of different semiconductor materials. By passing current through the connection surface of two semiconductor materials, electroluminescence effect is generated to convert electrical energy into light energy so that the light-emitting diode chips can not only emit light with high brightness but also save more energy.

In the structural design of the light-emitting diode chip, bonding wire electrodes will be provided on the surface of the chip. When the light-emitting diode wafer needs to be cut, flipped, or back-grinded during the manufacturing process, or during the chips subsequently being packaged and transported, most of the external components such as tapes or packaging materials are used to move or fix the light-emitting diode chips. In this way, the wire electrodes often directly contact or rub with external components, and would be contaminated with dirt or residual glue, which causes the conductive performance of the wire electrodes to decrease or even lose their conduction.

Therefore, how to design a light-emitting diode structure that can improve the aforementioned problems to protect the bonding wire electrodes is indeed a subject worthy of study.

### SUMMARY OF THE INVENTION

The main objective of the present invention is to provide a light emitting diode structure with an effect of protecting electrodes.

To achieve the above objective, the present invention discloses a light emitting diode structure, including a substrate, a semiconductor light emitting structure, an electrode, and a protection structure. The semiconductor light-emitting structure is located on the substrate, and the semiconductor light-emitting structure includes a top surface. The electrode is located on the top surface, and the electrode includes a pad portion and at least one extension portion. One end of each extension portion is connected to the pad portion, and the pad portion has a first maximum height away from the top surface. The protection structure is located on the top surface and connected to the electrode, and the protection structure has a second maximum height away from the top surface. Wherein the second maximum height is greater than the first maximum height.

In one embodiment of the light emitting diode structure of the present invention, the protection structure and the pad portion are integrally formed.

In one embodiment of the light emitting diode structure of the present invention, the pad portion and the at least one extension portion form at least one overlapping area, and the protection structure is a portion structure of the pad portion overlapped with the at least one extension portion in the at least one overlapping area.

In one embodiment of the light emitting diode structure of the present invention, the protection structure overlaps a portion area of the pad portion and the at least one extension portion.

In one embodiment of the light emitting diode structure of the present invention, the pad portion and the at least one extension portion have the same height.

In one embodiment of the light emitting diode structure of the present invention, the protection structure and the at least one extension portion have the same height.

In one embodiment of the light emitting diode structure of the present invention, the light emitting diode structure further includes a passivation layer overlapping a portion of the semiconductor light emitting structure and the electrode wherein the protection structure and the passivation layer are integrally formed.

In one embodiment of the light emitting diode structure of the present invention, the pad portion and the passivation layer form an overlapping area and the protection structure is a portion structure of the passivation layer overlapped with the pad portion in the at least one overlapping area.

In one embodiment of the light emitting diode structure of the present invention, the passivation layer is formed by an insulation material.

In one embodiment of the light emitting diode structure of the present invention, the second maximum height of the protection structure is not less than 0.5 μm.

In one embodiment of the light emitting diode structure of the present invention, the protection structure is formed by metal materials or oxide materials.

Accordingly, during the manufacturing, the packaging or the transportation processes, by incorporating the protective structure in the light emitting diode structure of the present invention, the pad portion of the electrode would be effectively isolated from external elements such as tape or packaging materials. In this way, the pad portion would be protected from directly contact or friction with external components and from being contaminated by dirt or residual glue. Therefore, the conductive performance of the pad portion would be ensured.

### BRIEF DESCRIPTION OF THE DRAWINGS

FIG. 1 is a top view of the first embodiment of the light emitting diode structure of the present invention.

FIG. 2 is a cross-sectional view of the first embodiment of the light emitting diode structure of the present invention.

FIG. 3 is a top view of the second embodiment of the light emitting diode structure of the present invention.

FIG. 4 is a cross-sectional view of the second embodiment of the light emitting diode structure of the present invention.

FIG. 5 is a top view of the third embodiment of the light emitting diode structure of the present invention.

FIG. 6 is a cross-sectional view of the third embodiment of the light emitting diode structure of the present invention.

FIG. 7 is a top view of the fourth embodiment of the light emitting diode structure of the present invention.

FIG. 8 is a cross-sectional view of the fourth embodiment of the light emitting diode structure of the present invention.

FIG. 9 is a cross-sectional view of the fifth embodiment of the light emitting diode structure of the present invention.

### DETAILED DESCRIPTION OF THE PREFERRED EMBODIMENT

Since various modifications and embodiments are only illustrative and not limiting, after reading this specification, those with ordinary skill in the art may conceive of other variations and embodiments that do not depart from the scope of the present invention. The features and advantages of such embodiments will be further highlighted based on the detailed description and the scope of the claims set forth below.

In this document, the terms “one” or “a” are used to describe the components and elements disclosed herein. This is done for convenience and to provide a general meaning to the scope of the present invention. Therefore, unless otherwise explicitly indicated, such descriptions should be understood to encompass one or at least one, and the singular also includes the plural.

In this document, terms like “first” or “second” and similar ordinal numbers are primarily used to distinguish or refer to similar or analogous components or structures, and do not necessarily imply an order in space or time. It should be understood that in certain situations or configurations, ordinal numbers can be used interchangeably without affecting the implementation of the present disclosure.

In this document, terms like “comprising,” “including,” “having,” or any similar expressions are intended to cover non-exclusively inclusive entities. For example, components or structures containing multiple elements are not limited solely to the listed elements in this document, but may include other elements that are typically inherent to the component or structure even if not explicitly listed.

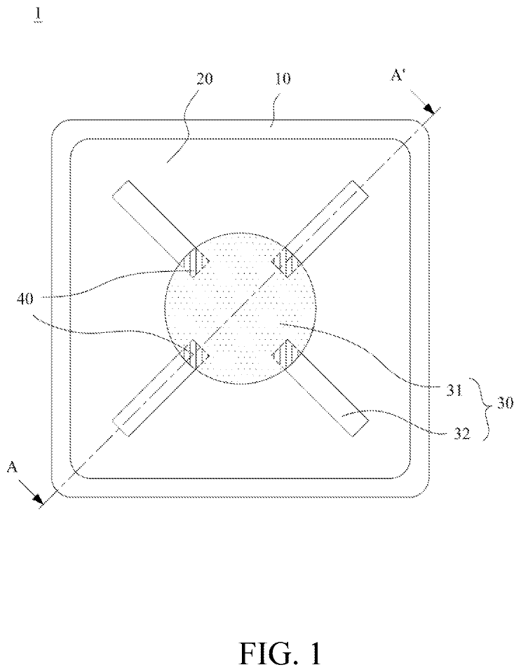

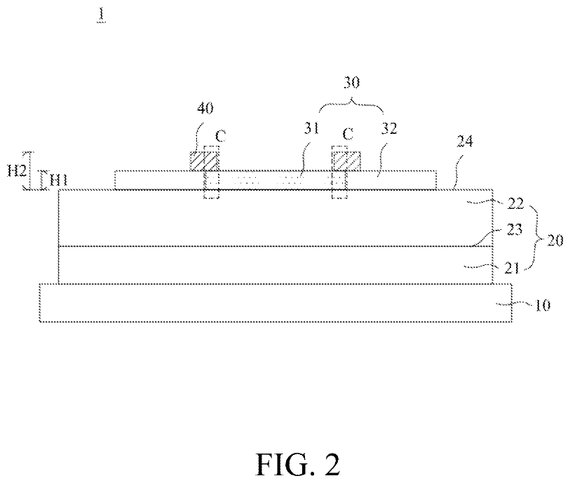

Please refer to FIG. 1 and FIG. 2 for the relevant illustrations of the first embodiment of the light emitting diode structure of the present invention, where FIG. 2 is a cross-sectional view along line A-A′ in FIG. 1. As shown in FIG. 1 and FIG. 2, the light emitting diode structure 1 of the present invention comprises a substrate 10, a semiconductor light emitting structure 20, an electrode 30, and a protection structure 40. The substrate 10 serves as the foundational component of the light emitting diode structure 1, and is primarily made of, but not limited to a silicon substrate in this embodiment.

The semiconductor light emitting structure 20 is located on the substrate 10, and it is utilized to generate electroluminescent effects and emit light. The semiconductor light emitting structure 20 includes a top surface 24, which is the side opposite to another side in contact with the substrate 10. In one embodiment of the present invention, the semiconductor light emitting structure 20 may further include a first semiconductor layer 21 and a second semiconductor layer 22. The first semiconductor layer 21 is adjacent to the substrate 10. In the below examples, gallium phosphide (GaP) is provided, but not limited to, the examples of the material for the first semiconductor layer 21. Other semiconductor materials can also be used for the first semiconductor layer 21. The first semiconductor layer 21 can be doped with different metals to form either an N-type semiconductor or a P-type semiconductor.

The second semiconductor layer 22 is located on the first semiconductor layer 21. In the following examples, aluminum gallium indium phosphide (AlGaInP) is provided, but not limited to, the examples of the material for the second semiconductor layer 22. Other semiconductor materials can also be used for the second semiconductor layer 22. The second semiconductor layer 22 can also be doped with different metals to form either an N-type semiconductor or a P-type semiconductor. Specifically, when the first semiconductor layer 21 is an N-type semiconductor, the second semiconductor layer 22 is a P-type semiconductor. Conversely, when the first semiconductor layer 21 is a P-type semiconductor, the second semiconductor layer 22 is an N-type semiconductor. A light emitting layer 23 is formed at the interface between the first semiconductor layer 21 and the second semiconductor layer 22 (i.e., the junction interface of the first semiconductor layer 21 and the second semiconductor layer 22). Moreover, the light emitting layer 23 is a multiple quantum well (MQW) layer.

The electrode 30 is located on the top surface 24 of the semiconductor light emitting structure 20, and it can be connected to a power source. By supplying power to the electrode 30, the light emitting layer 23 would emit light as current passes therethrough. In the present invention, the electrode 30 includes at least a pad portion 31 and at least one extension portion 32, with one end of each extension portion 32 connected to the pad portion 31. The pad portion 31 serves as a circuit for soldering and electrically connecting with other electronic components, while the extension portions 32 can serve as power extension paths to increase the emitting areas and their uniformity. Depending on different design requirements, the pad portion 31 and at least one extension portion 32 can have the same height, or there can be a height difference between them. In the present invention, the pad portion 31 has a first maximum height H1 away from the top surface 24, which means that the first maximum height H1 is defined as the maximum distance from the top surface 24 to the pad portion 31 along the vertical direction.

The protection structure 40 is located on the top surface 24 of the semiconductor light emitting structure 20 and is connected to the electrode 30. The primary purpose of the protection structure 40 is to block external components such as tapes or packaging materials from directly contacting the pad portion 31 of the electrode 30, thereby minimizing the risk of direct contact with the pad portion 31. In the present invention, the protection structure 40 has a second maximum height H2 away from the top surface 24. Specifically, the second maximum height H2 is defined as the maximum distance from the top surface 24 to the protection structure 40 along the vertical direction. Structurally, the second maximum height H2 of the protection structure 40 is greater than the first maximum height H1 of the pad portion 31. This ensures that when external components come into contact with the light emitting diode structure 1 of the present invention, they will first make contact with the protection structure 40 rather than the pad portion 31.

In one embodiment of the present invention, the second maximum height H2 of the protection structure is not less than 0.5 μm, preferably ranging from 0.5 μm to 5 μm. However, the present invention is not limited to this range. The protection structure 40 can be made of metal or oxide materials, or it can be made of insulation materials or materials identical to those of the electrode 30, depending on design requirements. Additionally, the protection structure 40 can be designed in any shape as a whole or a partial three-dimensional structure, such as, but not limited to, spherical, conical, block-like, cylindrical, strip-like, or ring-shaped.

In this embodiment, the protection structure 40 is integrally formed with the pad portion 31 of the electrode 30. This means that the protection structure 40 and the pad portion 31 can be formed together using the same material and process. For example, in the manufacturing process of the light emitting diode structure 1 of the present invention, the extension portion(s) 32 of the electrode 30 is first formed on the top surface 24 in the first process. Then, in the second process, the pad portion 31 of the electrode 30 and the protection structure 40 are formed on the top surface 24. In terms of structural design, the pad portion 31 and at least one extension portion 32 partially overlap to form at least one overlapping area C and the protection structure 40 is a portion structure of the pad portion 31 overlapped with the at least one extension portion 32 in at least one overlapping area C. Therefore, there is a height difference between the protection structure 40 and the pad portion 31 of the electrode 30. The protection structure 40 covers a portion area of the pad portion 31 and each extension portion 32, which means that the structure mentioned above can be considered as having the same height for the pad portion 31 and at least one extension portion 32.

In this embodiment, at least one extension portion 32 is a plurality of elongated structures which are spaced apart and divergently arranged. The pad portion 31, on the other hand, is a single circular structure. By overlapping the end portions of each elongated structure with the edge portion of the circular structure, multiple overlapping areas C are formed, resulting in the formation of multiple block-like protection structures 40. Through this design of the protection structure 40, external components that come into contact with the surface of the light emitting diode structure 1 of the present invention will only contact with the protection structure 40 but not the pad portion 31. Thus, the risk of the pad portion 31 getting contaminated or polluted by external substances would be decreased.

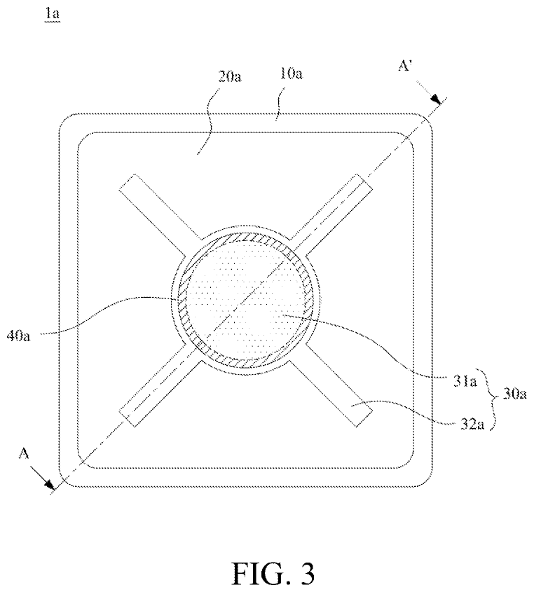

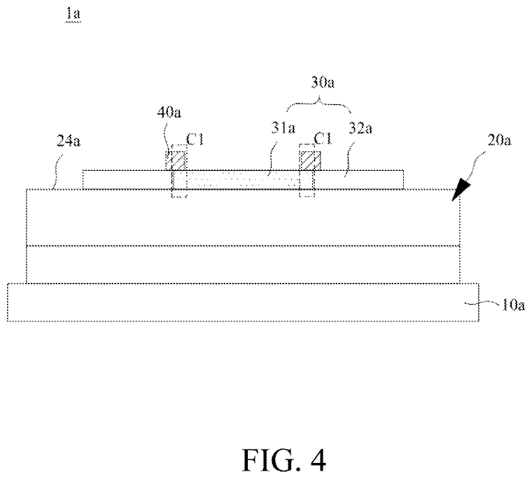

Please refer to FIG. 3 and FIG. 4 which show the relevant illustrations of the second embodiment of the light emitting diode structure of the present invention. FIG. 4 is a cross-sectional view along the line A-A′ in FIG. 3. This embodiment represents a variation of the first embodiment of the light emitting diode structure 1 of the present invention. As shown in FIG. 3 and FIG. 4, in this embodiment, the light emitting diode structure 1a of the present invention also adopts a two-step process to sequentially form at least one extension portion 32a and a pad portion 31a. The at least one extension portion 32a comprises a plurality of spaced apart and divergently arranged elongated structures, connected by a single hollow annular structure at the end of each elongated structure. The pad portion 31a is a single circular structure, with the inner edge portion of the annular structure overlapping with the edge portion of the circular structure to form an overlapping area C1 so that a single annular protection structure 40a is formed. Accordingly, the annular protection structure 40a substantially encloses the pad portion 31a so as the risk of the pad portion 31a being contaminated or polluted by external substances would effectively reduce.

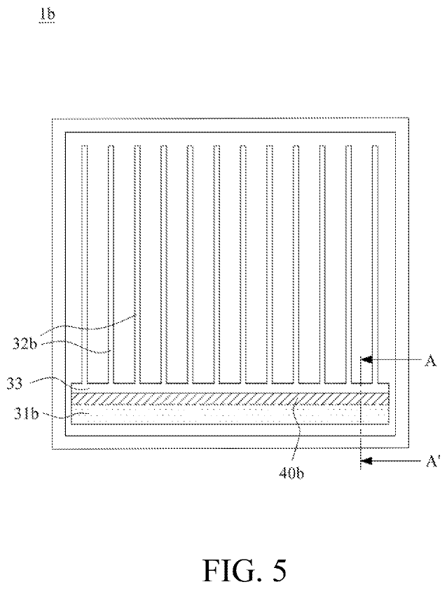

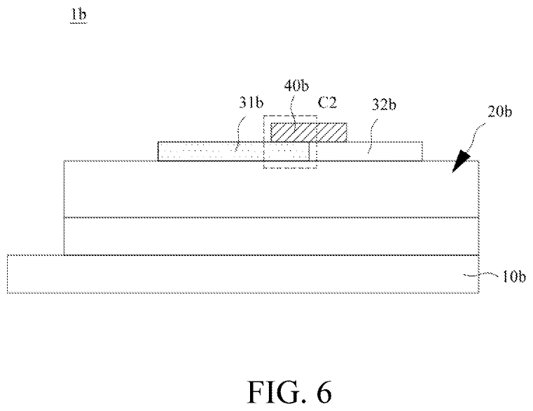

Please refer to FIG. 5 and FIG. 6 which show the relevant illustrations of the third embodiment of the light emitting diode structure of the present invention. FIG. 6 is a cross-sectional view along the line A-A′ in FIG. 5. As shown in FIG. 5 and FIG. 6, in this embodiment, the light emitting diode structure 1b of the present invention also adopts a two-step process to sequentially form at least one extension portion 32b and a pad portion 31b. The at least one extension portion 32b comprises a plurality of spaced apart and parallel elongated structures, with another elongated structure connecting the end of each elongated structure to serve as a busbar 33. The pad portion 31b is a single elongated structure. An overlapping area C2 is formed by overlapping one side edge of the elongated structure of the busbar with the opposite side edge of the elongated structure of the pad portion 31b and a single elongated protection structure 40b is formed accordingly. The pad portion 31b and at least one extension portion 32b have the same height. The second maximum height H2 of the protection structure here is greater than 5 μm, but the present invention is not limited to this range. Accordingly, the elongated protection structure 40b, designed to match the shape of the pad portion 31b, would provide an extended barrier effect and effectively reduce the area and the risk of the pad portion 31b being contaminated or polluted by external substances.

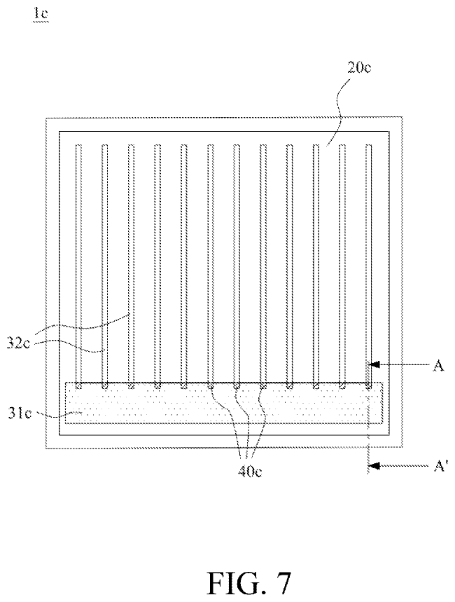

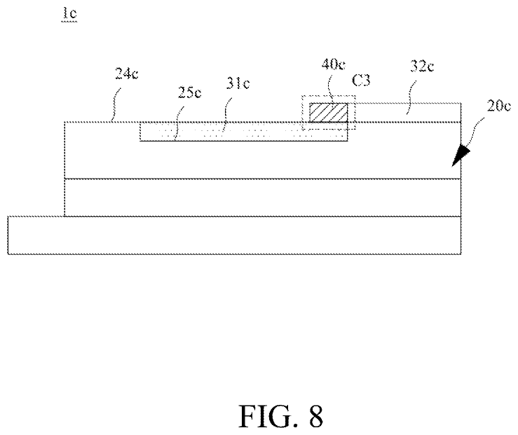

Please refer to FIG. 7 and FIG. 8 which show the relevant illustrations of the fourth embodiment of the light emitting diode structure of the present invention. FIG. 8 is a cross-sectional view along the line A-A′ in FIG. 7. This embodiment is a modification of the first embodiment of the light emitting diode structure 1b of the present invention. As shown in FIG. 7 and FIG. 8, in this embodiment, the light emitting diode structure 1c of the present invention is formed using a single process to simultaneously form at least one extension portion 32c and a pad portion 31c. Prior to the aforementioned process, a recess 25 is first formed on the top surface 24c of the semiconductor light emitting structure 20c. Subsequently, the aforementioned process is carried out to form the pad portion 31c within the recess 25, while simultaneously forming at least one extension portion 32c and a protection structure 40c on the top surface 24c. Furthermore, at least one extension portion 32c comprises a plurality of spaced apart and parallel elongated structures. The pad portion 31c is a single elongated structure and connects the end of each elongated structure of the extension portion 32c. An overlapping area C3 is formed by overlapping the end of each elongated structure with one side edge of the elongated structure of the pad portion 31c so that multiple elongated protection structures 40c are formed accordingly. The protection structure 40c and at least one extension portion 32c have the same height, and the pad portion 31c is lower than the protection structure 40c and at least one extension portion 32c. Therefore, through the design of the recess 25c, a height difference between the pad portion 31c and the protection structure 40c would be formed in the light emitting diode structure 1c of the present invention to facilitate an effective barrier protection for the pad portion 31c.

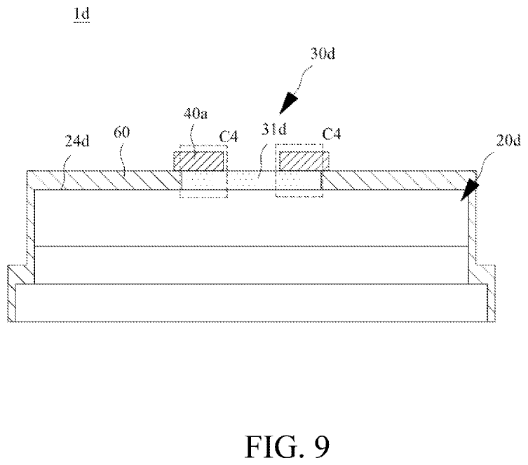

Please refer to FIG. 9 which show the relevant diagram of the fifth embodiment of the light emitting diode structure of the present invention. As shown in FIG. 9, in this embodiment, the light emitting diode structure 1d of the present invention first adopts a single process to form the electrode 30d, including the pad portion and at least one extension portion, on the top surface 24d of the semiconductor light emitting structure 20d. Then, in another process, a passivation layer 50 is formed on the outer surface of the semiconductor light emitting structure 20d, for example, including the top surface 24d and the side surface. Finally, the local passivation layer 50 covering the pad portion 31d on the electrode 30d is removed to expose the pad portion 31d. The protection structure 40d is integrally formed with the passivation layer 50. Furthermore, in the structural design, at least one overlapping area C4 is formed by overlapping the pad portion 31d of the electrode 30d partially with the passivation layer 50. The protection structure 40d is a partial structure of the passivation layer 50 overlapped with the electrode 30d in at least one overlapping area C4. The aforementioned passivation layer 50 is made of insulating material. Since a passivation layer is generally formed on the surface of a conventional light emitting diode, the protection structure 40d would be formed simultaneously as the passivation layer 50 being formed in the light emitting diode structure 1d of the present invention, Thus, the manufacturing process would be simplified and provide the protection for the pad portion of the electrode 30d.

Certainly, for the aforementioned embodiments, it is possible to achieve the same effect as the previous embodiments by first forming the electrode with a single process, and then forming the protection structure with another process, whether using different materials for the protection structure and the electrode, or without considering the complexity of the process.

The above embodiments are essentially provided for auxiliary explanation, and are not intended to limit the embodiments of the claimed subject matter or their applications or uses. Furthermore, even though at least one illustrative embodiment has been presented in the foregoing embodiments, it should be understood that there can still be numerous variations within the scope of the invention. It should also be understood that the embodiments described herein are not intended to limit the scope, application, or configuration of the claimed subject matter in any way. On the contrary, the foregoing embodiments will provide a convenient guide for those skilled in the art to implement one or more embodiments of the claimed subject matter. Moreover, various changes in the functionality and arrangement of components can be made within the scope defined by the claims, and the claims encompass known equivalents and foreseeable equivalents at the time of filing this patent application.

What is claimed is:

1. A light emitting diode structure, including:
a substrate;
a semiconductor light emitting structure, located on the substrate, including a top surface;
an electrode, located on the top surface, including a pad portion and at least one extension portion, one end of each the extension portion being connected to the pad portion, the pad portion including a first maximum height away from the top surface; and
a protection structure, located on the top surface and connected to the electrode, including a second maximum height away from the top surface, wherein the second maximum height is greater than the first maximum height.

2. The light emitting diode structure of claim 1, wherein the protection structure and the pad portion are integrally formed.

3. The light emitting diode structure of claim 2, wherein the pad portion and the at least one extension portion form at least one overlapping area, and the protection structure is a portion structure of the pad portion overlapped with the at least one extension portion in the at least one overlapping area.

4. The light emitting diode structure of claim 1, wherein the protection structure overlaps a portion area of the pad portion and the at least one extension portion.

5. The light emitting diode structure of claim 1, wherein the pad portion and the at least one extension portion have the same height.

6. The light emitting diode structure of claim 1, wherein the protection structure and the at least one extension portion have the same height.

7. The light emitting diode structure of claim 1, further including a passivation layer overlapping a portion of the semiconductor light emitting structure and the electrode wherein the protection structure and the passivation layer are integrally formed.

8. The light emitting diode structure of claim 7, wherein the pad portion and the passivation layer form an overlapping area and the protection structure is a portion structure of the passivation layer overlapped with the pad portion in the at least one overlapping area.

9. The light emitting diode structure of claim 7, wherein the passivation layer is formed by an insulation material.

10. The light emitting diode structure of claim 1, wherein the second maximum height of the protection structure is not less than 0.5 μm.

11. The light emitting diode structure of claim 1, wherein the protection structure is formed by metal materials or oxide materials.
